(19) United States
(12) Patent Application Publication
(10) Pub. No.: US 2013/0326315 A1
(43) Pub. Date: Dec. 5, 2013

(54) EVALUATION OF POLYNOMIALS OVER FINITE FIELDS AND DECODING OF CYCLIC CODES

(71) Applicants: Michele Elia, Castiglione Torinese (TO) (IT); Joachim Jakob Rosenthal, Zollikon (CH); Davide Mose' Schipani, Zurich (CH)

(72) Inventors: Michele Elia, Castiglione Torinese (TO) (IT); Joachim Jakob Rosenthal, Zollikon (CH); Davide Mose' Schipani, Zurich (CH)

(73) Assignee: UNIVERSITAT ZURICH, Zurich (CH)

(21) Appl. No.: 13/980,317

(22) PCT Filed: Jan. 18, 2012
(86) PCT No.: PCT/EP2012/050704

§ 371 Date: Jul. 18, 2013

(30) Foreign Application Priority Data
Jan. 18, 2011 (CH) 00085/11

(51) Int. Cl. H03M 13/15

(52) U.S. Cl. CPC H03M 13/157
USPC 714/785; 714/752

(57) ABSTRACT

An apparatus and method are disclosed for evaluating an input polynomial (p(x)) in a (possibly trivial) extension of the finite field of its coefficients, which are useful in applications such as syndrome evaluation in the decoding of cyclic codes. The apparatus comprises a decomposition/evaluation module (110) configured to iteratively decompose the input polynomial into sums of powers of the variable x, multiplied by powers of transformed polynomials, wherein each transformed polynomial has a reduced degree as compared to the input polynomial, and to evaluate the decomposed input polynomial. In another aspect, an apparatus and method of identifying errors in a data string based in a cyclic code are disclosed, which employ the Cantor-Zassenhaus algorithm for finding the roots of the error-locator polynomial, and which employ Shank's algorithm for computing the error locations from these roots.

### TECHNICAL FIELD

The present invention relates to an apparatus for efficiently evaluating a polynomial over a finite field, and to a corresponding method. The present invention further relates to an apparatus for identifying errors in a data string based on a cyclic code, and to a corresponding method.

### PRIOR ART

Evaluation of polynomials over finite fields is an important problem in a large number of applications. Examples include error detection schemes in the context of cyclic codes. Such schemes are widely employed for the encoding and decoding of (normally binary) data to be transmitted across some imperfect transmission channel such as a digital rf transmission channel, write/read operations on a medium such as a CD or DVD etc. Due to noise or impairments of the transmission channel, the transmitted data may become corrupted. To identify and correct such errors, so-called forward error correction schemes have been developed. Such schemes employ cyclic codes over a finite field. Well known classes of error-correcting cyclic codes are the so-called Reed-Solomon codes or, more generally, the so-called BCH codes (see references [1], [2]).

A finite field (also known as a Galois field) is a field composed of a finite number of elements. The number of elements in the field is called the order or cardinality of the field.

This number is always of the form p^{m}, where p is a prime number and m is a positive integer. A Galois field of order q=p^{m} will in the following be designated either as GF(p^{m}) or as F_{q}, these symbols being fully synonymous. A polynomial over an arbitrary field (including a finite field) will be designated as P(x), as p(x) or a similar symbol. An element in which the polynomial is to be evaluated will in the following be designated by lower-case Greek letters such as α, β or γ. The definitions and properties of finite fields are described in many standard textbooks of mathematics, e.g., [12] or [14], and reference is made to such standard textbooks for details.

The well known Horner's rule is a universal algorithm for evaluating a polynomial which works in any field, including finite fields. This algorithm computes the value P(α) of a polynomial

P(x)=aₙxⁿ+aₙ₋₁xⁿ⁻¹ . . . +a₀

in an iterative manner as suggested by the following formula:

( . . . ((aₙα+aₙ₋₁)α+aₙ₋₂)α+ . . . )α+a₁)α+a₀.

In many applications over finite fields, however, this algorithm is not very efficient and requires significant computational efforts in terms of CPU time and memory usage. Furthermore, Horner's rule is inherently serial in nature and cannot readily be parallelized.

WO 99/37029 proposes a device and method of evaluating a polynomial more efficiently. The polynomial is split into sub-polynomials, which are then evaluated in the usual manner using Horner's rule. While this approach allows for better parallelization, there is still much room for improvement in terms of computational complexity, especially when the order of the polynomial becomes large.

A standard method of decoding a cyclic code up to the BCH bound is the Gorenstein-Peterson-Zierler decoding procedure. This procedure comprises four steps:
Computation of 2t syndromes, where t is the BCH bound
Computation of the error-locator polynomial
Computation of the roots of the error-locator polynomial, yielding the error positions.
Computation of the error magnitudes.

Evaluation of polynomials is extensively involved in particular in the first and fourth steps. The second step is usually efficiently done through Berlekamp-Massey algorithm. For the third step, usually an algorithm called the Chien search is employed. This algorithm may however be unacceptably slow if the error-locator polynomial has a large degree. It is therefore desirable to provide an apparatus and method that allow to determine the error positions in a more efficient manner than by the Chien search.

### SUMMARY OF THE INVENTION

In a first aspect, it is an object of the present invention to provide an apparatus for efficiently evaluating a polynomial over a finite field. This object is achieved by an apparatus having the features laid down in claim 1.

It is a further object of the present invention to provide an efficient computer-implemented method of evaluating a polynomial over a finite field. This object is achieved by a method as laid down in claim 11.

In a second aspect, it is an object of the present invention to provide an apparatus for efficiently identifying errors in a data string based on a cyclic code, in particular, for locating the error positions in the data string in an efficient manner. This object is achieved by an apparatus having the features laid down in claim 9.

It is a further object of the present invention to provide an efficient computer-implemented method for efficiently identifying errors in a data string, in particular, for efficiently locating the error positions. This object is achieved by a method as laid down in claim 17.

Further embodiments of the invention are laid down in the dependent claims.

### BRIEF DESCRIPTION OF THE DRAWINGS

Preferred embodiments of the invention are described in the following with reference to the drawings, which are for the purpose of illustrating the present preferred embodiments of the invention and not for the purpose of limiting the same. In the drawings,

FIG. 1 shows a first embodiment of an apparatus according to the present invention, for evaluating a polynomial over any finite field;

FIG. 2 shows a second embodiment of an apparatus according to the present invention for evaluating a polynomial over a binary field; and

FIG. 3 shows a third embodiment of an apparatus according to the present invention, for correcting errors in a cyclic code.

### DESCRIPTION OF PREFERRED EMBODIMENTS

### Apparatus and Algorithm for Evaluating Polynomials: Preliminary Considerations

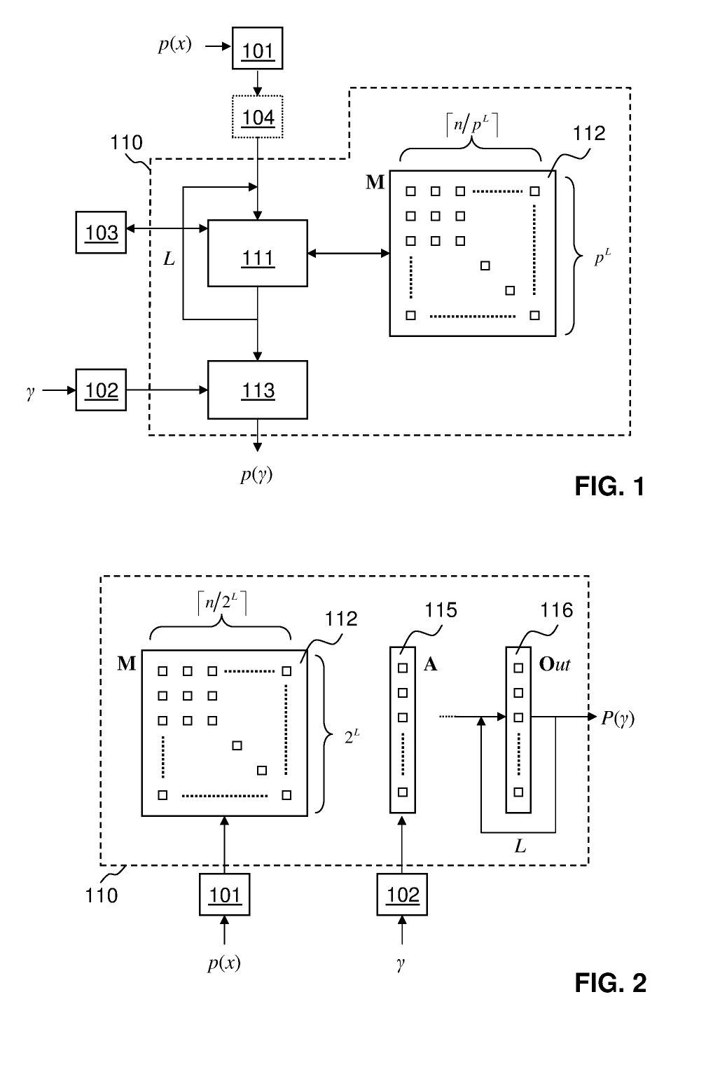

A first embodiment of the present invention is described in the following with reference to FIG. 1. The apparatus of FIG. 1 may be implemented either in hardware or in software as a program for a general-purpose computer or for a dedicated digital signal processor, the program carrying out a method as described herein when being executed on the computer. The apparatus of FIG. 1 is partitioned into conceptually separate sub-devices that may allow significantly different hardware or software implementations. Each sub-device can be implemented stand-alone and will be called block or module. However, it is also possible to integrate the functionalities of several of the sub-devices into a single device, or to implement the functionalities of several of the blocks in a single portion of software code that cannot be readily separated into individual blocks, as will be seen in connection with the embodiment of FIG. 2 further below.

The apparatus of FIG. 1 executes an algorithm for evaluating polynomials over finite fields, hereafter called the “Algorithm”. The relevant finite field is denoted GF(p^{m}), p prime and m positive integer. A polynomial p(x) of degree n is defined, which is identified by its coefficient vector P having n+1 entries from GF(p^{m}) or from a subfield GF(p^{r}), where r is a divisor of m. The polynomial p(x) is evaluated in x=γ, an element of GF(p^{m}). The element γ may be represented in a polynomial basis

[symbol]

={1,α, . . . ,α^{m-1}}

of GF(p^{m}), where α is a root of a primitive polynomial g(x) of degree m over GF(p). Then γ may be written as

γ=a₀+a₁α+ . . . +aₘ₋₁α^{m-1}

and it is uniquely identified by an m-dimensional vector with entries in GF(p),

α=[a₀,a₁, . . . ,aₘ₋₁].

A primitive element β in the subfield GF(p^{r}) is taken to be the power of α with exponent

$$\frac{{p}^{m} - 1}{{p}^{r} - 1}$$

and may also be represented in the base [symbol] :

β=b₀+b₁α+ . . . +bₘ₋₁α^{m-1},

thus, it is uniquely identified by an m-dimensional vector with entries in GF(p)

β=[b₀,b₁, . . . ,bₘ₋₁].

It is observed that in a large number of applications the coefficients of p(x) are either in the finite field GF(p) or in the extension field GF(p^{m}): the complexity of the Algorithm in the two fields is very different, but strictly connected.

### General Structure of the Implementation of FIG. 1

In general terms, the apparatus (and consequently also the Algorithm) of FIG. 1 is structured as follows:

Inputs of the algorithm:
a vector P, corresponding to p(x), whose entries are the coefficients of the powers of x in p(x) which are elements of a finite field GF(p^{r}), which is a subfield of GF(p^{m}), possibly GF(p^{m}) itself; and
an element γ in GF(p^{m}) in which the polynomial p(x) is to be evaluated.

These inputs are entered into the apparatus or read (received) by the apparatus by a coefficient-receiving module 101 and by an input value-receiving module 102.

An optional iteration determining module 103 reads or calculates the desired or optimum number of iterations L. Alternatively, the number of iterations may be predetermined and hard-coded into the apparatus or software (e.g., in applications where the degree n of the polynomial is fixed).

An optional initialization submodule 104 optionally decomposes the input polynomial into a sum of polynomials with coefficients in a subfield GF(p) of order p, as detailed further below (see Remark 4).

In a decomposition and evaluation module 110, a p^{L}×┌n/p^{L}┐ matrix 112 is defined that is used to store the coefficients of the polynomials into which p(x) is partitioned. The apparatus then iteratively carries out a decomposition of the polynomial into a sum of smaller entities (powers of smaller polynomials multiplied by powers of the variable x) by looping over a splitter module 111 for a number of L times, using the matrix 112 to store the coefficients after each iteration.

In an evaluation module 113, the apparatus evaluates the smallest polynomials obtained by looping over the splitter module 111 and computes the output value p(γ) of the polynomial starting from the data produced by the splitter module 111.

The output of the apparatus and algorithm is the value p(γ).

### Special Case: Binary Coefficients

In the following, the special prime p=2 will be treated separately since the corresponding fields have peculiar properties that are not shared by the other finite fields, which allows for some further simplifications of the algorithm for p=2. Since in this case the Algorithm can be explained and understood more easily, it will be described first, as an introduction to the more general ideas discussed subsequently.

In practice, the coefficients of the polynomial will often be binary numbers, i.e., the coefficients will be elements of GF(2), and the polynomial will be evaluated in an element of an extension field GF(2^{m}) with m>1. In this case, the above-described algorithm may be implemented particularly efficiently. This will be explained in more detail in the following, referring to the evaluation of a polynomial p(x), with coefficients in GF(2), in a point γεGF(2^{m}) with m>1.

Any polynomial p(x) with binary coefficients can be written as a sum of two polynomials by collecting odd and even powers of x:

p(x)=xp₁(x²)+p₂(x²)=xp₁(x)²+p₂(x)²,

where p₁(x) has degree not greater than └(n−1)/2┘ and p₂(x) has a degree not greater than └n/2┘, where half brackets └•┘ denote the familiar floor function which rounds the argument to the largest previous integer, and half brackets ┌•┐ denote the familiar ceiling function which rounds the argument to the smallest following integer.

Therefore, knowing p₁(γ) and p₂(γ), the value p(γ) can be obtained as

p(γ)=p₁(γ)²+γ·p₂(γ)²,

performing two squares, one multiplication, and one sum in GF(2^{m}).

Clearly, the procedure can be iterated: at each i-th step, the number of polynomials pᵢⱼ(x) doubles, i.e., j varies between 1 and 2ⁱ, and their degree is divided roughly by 2. The number of squares at each step is equal to the number of polynomials, and the number of multiplications by γ is half the number of polynomials, as is the number of additions.

After L steps it is necessary to evaluate 2^{L} polynomials of degree nearly n/2^{L}, then p(γ) is reconstructed performing back the operations previously described. The total cost of the procedure, in terms of multiplications and additions, is composed of the following partial costs:

Evaluation of 2^{L} polynomials p_{Lj}(X), of degree ┌n/2^{L}┐ at the same point γ.
Computation of 2+2²+ . . . +2^{L}=2^{L+1}−2 squares.
Computation of 1+2+2²+ . . . +2^{L-1}=2^{L}−1 multiplications by γ.
Computation of 1+2+2²+ . . . +2^{L-1}=2^{L}−1 additions.

The fastest way to evaluate 2^{L} polynomials at the same point is to evaluate the powers γ^{h} for

$$h = 2 , … , ⌈ \frac{n}{{2}^{L}} ⌉$$

and to obtain each p_{Lj}(γ) by adding those powers corresponding to non-zero coefficients; the number of additions per each polynomial is nearly n/2^{L}, then the total number of additions is not more than n.

### Remark 1.

The actual number of additions is much less if sums of equal terms can be reused, and it is upper bounded by O(n/ln(n)). This bound is a consequence of the fact that in order to evaluate 2^{L} polynomials of degree h=┌n/2^{L}┐ at the same point β, we have to compute 2^{L} sums of the form

γⁱ^{₁}+ . . . +γⁱ^{ₕ},

having at disposal the h powers γᵢ. One can then think of a binary matrix of dimensions

2L×┌n/2^{L}┐

to be multiplied by a vector of powers of γ, and assuming

$${2}^{L} \approx \frac{n}{{2}^{L}}$$

(as will be shown below), one may consider the matrix to be square and apply Theorem 2 of Ref. [11].

To establish how many iterations L should be used, one may minimize the total number of multiplications (since multiplications are much more costly than additions, additions may be neglected). The best choice for L is obtained when the total number of multiplications ┌n/2^{L}┐ required to compute the powers of γ entering the evaluations of p_{Lj}(γ) is roughly equal to the number 2^{L+1}−2+2^{L}−1 (which is approximately 3·2^{L}) of multiplications required to reconstruct p(γ). This yields an approximate equation for L:

$$\frac{n}{{2}^{L}} \approx 3 \cdot {2}^{L}$$

which gives the approximate value

$${2}^{L} \approx \frac{\sqrt{n}}{3} .$$

Then, the total number N of multiplications in GF(2^{m}) required for evaluating p(γ) is

N=2(3·2^{L})≈\sqrt{12n}.

Numerical comparisons, reported in the following Table, indicate that the advantage of the proposed method for evaluating the polynomials with respect to Horner's rule can be significant already for small n:

| n | Mₚ, Horner's rule | Mₚ, New Alg. |
|---|---|---|
| 12 | 11 | 12 |
| 16 | 15 | 11 |
| 32 | 31 | 23 |
| 64 | 63 | 27 |
| 256 | 255 | 109 |

### Remark 2.

When the polynomial p(x) has coefficients in GF(2^{r}), let β be an element (primitive) of GF(2^{r}) defining a basis for this field, then p(x) can be written as

p(x)=p₀(x)+βp₁(x)+β²p₂(x)+ . . . +β^{r-1}pᵣ₋₁(x),

where pᵢ(x), i=0, . . . , r-1, are polynomials over GF(2). Therefore, the problem of evaluating p(γ) is reduced to the problem of evaluating r polynomials pᵢ(x) with binary coefficients in the point γεGF(2^{m}), followed by the computation of r-1 products and r-1 sums in GF(2^{m}). The total complexity is approximately r·\sqrt{12n}.

There are also other options for computing p(γ) which may give a smaller number of multiplications, in any case the proposed strategy gives an upper bound (possibly tight) to the sufficient number of multiplications for computing p(γ).

In the following, a more general description of the Algorithm will be provided, which is not restricted to polynomials with binary coefficients.

### General Case: Coefficients in a Finite Field GF(p^{r})

Consider a polynomial P(x) of degree n over a finite field GF(p^{r}), and let γ denote an element of GF(p^{m}), r being a divisor of m. One may write P(x) as

P₀(x^{p})+xP₁(x^{p}) . . . +x^{p-1}Pₚ₋₁(x^{p}),

where P₀(x^{p}) collects the powers of x with exponent a multiple of p and xⁱPᵢ(x^{p}) collects the powers of the form x^{ap+i}.

If σ is the Frobenius automorphism of GF(p^{m}) mapping γ to γ^{p}, one can write the expression above as

P₀⁻¹(x)^{p}+xP₁⁻¹(x)^{p} . . . +x^{p-1}Pₚ₋₁⁻¹(x)^{p},

where Pᵢ⁻¹(x), and in general Pᵢ^{-k}(x) stand for the polynomials obtained from the corresponding Pᵢ(x) by substituting their coefficients with their transforms through the automorphism σ^{-k} for every k. Notice that the polynomials Pᵢ⁻¹(x) have degree at most ┌(n−i)/p┐. One can take the exponent out of the brackets as the field has characteristic p.

P(γ) for a particular value γ can be then obtained from {Pᵢ⁻¹(x)} by making p p-th powers, p−1 multiplications and p−1 sums.

If the procedure is iterated for L steps, then the total cost of evaluating P(γ) comprehends the following:
Evaluation of p^{L} polynomials of degree ┌n/P^{L}┐ in γ.
Computation of

$$p + {p}^{2} + ⋯ + {p}^{L} = \frac{{p}^{L + 1} - p}{p - 1}$$

p-th powers.
Computation of

p−1+(p²−P)+ . . . +p^{L}−p^{L-1}=p^{L}−1
multiplications by powers of γ.
Computation of

p−1+(p²−P)+ . . . +p^{L}−p^{L-1}=p^{L}−1
additions.
Computation of the coefficients of the p_{L} polynomials through σ^{-L}; the number of coefficients is the same as the number of coefficients of P(x), that is at most n+1, which would possibly imply too many multiplications. However, one can spare a lot, if one does the following: one evaluates the p^{L} polynomials in σ^{L}(γ) and then one applies σ^{-L} to the outputs. So one needs to apply powers of σ a number of times not greater than p^{L}+1. Notice also that what matters in σ^{L} is L modulo r because σ^{r} is the identity automorphism in GF(p^{r}), the field of the coefficients of the polynomial.

So altogether one would like to minimize the following number of multiplications:

$$G ( L ) = 2 ⌊ {log}_{2} p ⌋ \frac{{p}^{L + 1} - p}{p - 1} + {p}^{L} - 1 + 2 ⌊ {log}_{2} p ⌋ ( r - 1 ) ( {p}^{L} + 1 ) + \frac{n}{{p}^{L}} ( {p}^{r} - 1 ) ,$$

where 2└log₂ p┘ refers to a p-th power made by successive squaring (the factor 2 in front of └log₂ p┘ is substituted by 1 when p is 2), the automorphism σ^{L} counts like a power with exponent p^{L}, with L≦r-1, and ┌n/P^{L}┐ are the powers of γ we need to compute, while p^{r}−1 are all their possible nonzero coefficients. Once all the powers of γ have been multiplied by the possible coefficients, one actually needs also to compute at most n additions to get the value of the polynomials.

### Remark 3

If the coefficients are known to belong to GF(p), then the total cost is at most

$$2 ⌊ {log}_{2} p ⌋ \frac{{p}^{L + 1} - p}{p - 1 } + {p}^{L} - 1 + \frac{n}{{p}^{L}} ( p - 1 ) ,$$

since σ does not change the coefficients in this case. Then the best value for L is nearly

$${log}_{p} ( \frac{\sqrt{n ( p - 1 )}}{\sqrt{1 + 2 ⌊ {log}_{2} p ⌋ \frac{p}{p - 1}}} ) .$$

### Remark 4.

Given the previous Remark, one may look back at the general picture where the polynomial p(x) has coefficients in GF(p^{r}), with r being a divisor of m. If β is an element of GF(p^{r}) defining a power basis, then p(x) can be written as

p(x)=p₀(x)+βp₁(x)+β²p₂(x)+ . . . +β^{r-1}pᵣ₋₁(x),

where pᵢ(x), i=0, . . . , r-1, are polynomials over GF(p). Thus p(γ) can be obtained as a linear combination of the r numbers pᵢ(γ). Therefore, the problem of evaluating p(γ) is reduced to the problem of evaluating r polynomials pᵢ(x) with p-ary coefficients followed by the computation of r-1 products and r-1 sums in GF(p^{m}).

The total complexity is approximately

r\sqrt{8n(p-1)└log₂ p┘}.

In the binary case, that is if p=2, the complexity is r·\sqrt{12n}.

This initial decomposition may be optionally carried out in the initialization submodule 104 of FIG. 1.

### Variants

The invention can also be put in practice with different arrangements in the order of the steps. A variant is for example the following: if we suppose the coefficients to be in GF(p), we can obtain P(γ) as the linear combination

P₀(σ(γ))+αP₁(σ(γ))+ . . . +α^{p-1}Pₚ(σ(γ)),

the notation being slightly amended as compared to above, however with the same meaning as before. A possible strategy is now to evaluate recursively the powers γ^{j} for j from 2 up to p, and σ(γ)ᵢ from j from 2 up to the integer part of n/p, compute the p numbers P_{1,i}(σ(γ)) using n sums and at most (p−2)n/p products (the powers of σ(γ) times their possible coefficients), and obtain P(γ) with p−1 products and p−1 additions. The total number Mₚ(n) of multiplications is 2p−3+(p−1)n/p at most. The mechanism can be iterated, smaller polynomials are obtained, and after L steps the total cost includes p−1 products to evaluate the first p powers of α; L−1 products to evaluate the first L powers of σ(γ); (p−2)(L−1) products to evaluate (σᵢ(γ)^{j}, i=1, . . . , L−1, j=2, . . . , p−1; at most n/p^{L} products to evaluate powers of σ^{L}(γ); at most (p−2) n/p^{L} products to evaluate the polynomials in the final step in σ^{L}(γ); p−1 multiplications by powers of σ(γ).

This argument can be generalized when the coefficients are in a bigger subfield.

### Example

### Practical Implementation of the Algorithm for Binary Coefficients

An example of a practical implementation of the algorithm for binary coefficients and of a corresponding apparatus is illustrated in FIG. 2. In this example, decomposition and evaluation of the input polynomial are not carried out in separate blocks (as was the case in the embodiment of FIG. 1), but are carried out in a single procedure.

In the following, loops within the algorithm are conventionally written in the form

for j from n₁ to n₂ do

. . .
executable statements
. . .

end do

which, borrowed from the semantic of MAPLE, is self-explicative. The following example concerns the case of p=2. The description for finite fields of odd characteristic can be obtained from this making the obvious adaptations.

### Input:

1. The prime p=2 and the exponent m specifying the field, and the degree n of the polynomial p(x). These quantities may be pre-configured in the apparatus or read from a memory.
2. Optionally: The field polynomial generator g(x) of degree m which specifies α.
3. The vector P of dimension n+1 with the coefficients of the polynomial p(x). This vector is entered by a coefficient-receiving module 101.
4. The field element γ in which p(x) is evaluated. This element is entered by an input element receiving module 102.

Initially, the optimal number L of iterations (or steps) is computed or may be pre-computed, using the expression \sqrt{12n}, and a matrix M (reference sign 112) of size 2^{L}×┌n/2^{L}┐ is generated in memory.

The matrix M is now loaded with the entries taken from P; this operation consists in a loop of length n+1, i.e. the index l varies from 0 to n, and at each step the following operations are executed:

```
for l from 0 to n do
  i = l mod 2^{L}
  $j = ⌊ \frac{l}{{2}^{L}} ⌋$
  M[i + 1, j + 1] = P[l]
end do
```

A column vector A (reference sign 115) of dimension ┌n/2^{L}┐ is loaded with the consecutive powers γ^{j-1} for j from 1 to ┌n/2^{L}┐.

The initial values p_{Lj}(γ) are computed and stored in vector Out (reference number 116) of dimension 2^{L}, i.e. the matrix product Out=MA is computed as follows:

(a)

```
for i from 1 to 2^{L} do
  varsum := 0
  $for j from 1 to ⌈ \frac{n}{{2}^{L}} ⌉$
    varsum := varsum + M[i, j]A[j]
  end do
    Out[i] := varsum
end do
```

A loop of length L is started, at each cycle the number of pᵢⱼ(γ) is halved, until only one value is obtained and the algorithm stops. Defining a vector OUT of dimension 2^{L-1}, the operations are

1.

for j from 1 to L do

for i from 1 to 2^{L-j} do

OUT[*] := Out[i]² + γOut[i + 2^{L-j}]²

end do
for i from 1 to 2^{L-j} do

Out[i]:=OUT[i]

end do

end do

| | |
|---|---|
| 2. | output p(γ) = Out[1] |

### Example

### Test Simulation Programs in MAPLE

The algorithm has been simulated in MAPLE for test purposes only. The MAPLE programs are given below along with simulation times which show that already in a poor software implementation significant gain can be observed. Implementation in, e.g., the C language, assembler, or hardware implementation will give even better performances.

To reliably estimate the evaluation time, an external loop is executed for evaluating the same polynomial in a number N=1000 of points. If T is the measured time, then T/N is a good estimation for the time required to evaluate the polynomial in a single point.

The polynomial has been chosen randomly with an average number of non-zero coefficients approximately close to n/2. This situation is typical of the polynomials that represents received code words.

### Horner's Rule.

The Horner rule is a simple loop of length n:

> #BCH code (127,85,13) Computation of 3 syndromes 1000 times

| > | gz7 := z\hat{ }7+z+1; | |
|---|---|---|
| > | cof7:=vector(127,[ ]): | |
| > | r(x) := | x\hat{ }126+x\hat{ }125+x\hat{ }123+x\hat{ }121+x\hat{ }120+x\hat{ }118+x\hat{ }115+x\hat{ }114+x\hat{ }111+ |

x\hat{ }110+x\hat{ }107+x\hat{ }106+x\hat{ }105+x\hat{ }103+x\hat{ }102+x\hat{ }98+x\hat{ }94+x\hat{ }89+
x\hat{ }87+x\hat{ }86+x\hat{ }85+x\hat{ }81+x\hat{ }79+x\hat{ }77+x\hat{ }76+x\hat{ }74+x\hat{ }73+x\hat{ }72+x\hat{ }70+
x\hat{ }69+x\hat{ }68+x\hat{ }62+x\hat{ }58+x\hat{ }52+x\hat{ }51+x\hat{ }50+x\hat{ }48+x\hat{ }47+x\hat{ }41+x\hat{ }39+
x\hat{ }36+x\hat{ }32+x\hat{ }30+x\hat{ }29+x\hat{ }26+x\hat{ }24+x\hat{ }23+x\hat{ }22+x\hat{ }21+x\hat{ }19+x\hat{ }18+
x\hat{ }15+x\hat{ }13+x\hat{ }9+x\hat{ }8+x\hat{ }7+x\hat{ }6+x\hat{ }3+x\hat{ }2+x+1;

| | |
|---|---|
| > | for j1 from 0 to 126 do cof7[j1+1]:=coeff(r(x),x,126−j1): od: |

> print(cof7):
[1, 1, 0, 1, 0, 1, 1, 0, 1, 0, 0, 1, 1, 0, 0, 1, 1, 0, 0, 1, 1,

1, 0, 1, 1, 0, 0, 0, 1, 0, 0, 0, 1, 0, 0, 0, 0, 1, 0, 1, 1, 1,
0, 0, 0, 1, 0, 1, 0, 1, 1, 0, 1, 1, 1, 0, 1, 1, 1, 0, 0, 0, 0,
0, 1, 0, 0, 0, 1, 0, 0, 0, 0, 0, 1, 1, 1, 0, 1, 1, 0, 0, 0, 0,
0, 1, 0, 1, 0, 0, 1, 0, 0, 0, 1, 0, 1, 1, 0, 0, 1, 0, 1, 1, 1,
1, 0, 1, 1, 0, 0, 1, 0, 1, 0, 0, 0, 1, 1, 1, 1, 0, 0, 1, 1, 1, 1]

> ts:=time( ): Sin:=vector(6,[ ]):
> for jk from 1 to 1000 do

| | |
|---|---|
| > | for j2 from 0 to 5 do jj:=2*j2+1: s1:=cof7[1]*z\hat{ }jj: |

for j1 from 2 to 126 do s2:=rem((s1+cof7[j1])*z\hat{ }jj,gz7,z) mod 2:

s1:=s2: od:

Sin[j2+1]:=sort(rem(s1+cof7[127],gz7,z) mod 2,z):

od: od:

| | |
|---|---|
| > | telap=time( )−ts; |

telap = 228.017

### The Algorithm.

The algorithm has been implemented considering several simple loops of length not larger than \sqrt{n}. The input is the same used with the Horner's rule.

| | |
|---|---|
| > | #R_IJ(x) polynomials |

| | |
|---|---|
| > | Fe7[1] := x\hat{ }15+x\hat{ }9+x\hat{ }6+x\hat{ }4+x\hat{ }3+x+1 |
| | Fe7[2] := x\hat{ }9+x\hat{ }8+x\hat{ }6+x\hat{ }4 |
| | Fe7[3] := x\hat{ }14+x\hat{ }13+x\hat{ }12+x\hat{ }9+x\hat{ }7+x\hat{ }6+x\hat{ }3+x\hat{ }2+1 |
| | Fe7[4] := x\hat{ }15+x\hat{ }14+x\hat{ }34+x\hat{ }12+x\hat{ }11+x\hat{ }10+x\hat{ }8+x\hat{ }7+x\hat{ }3+x\hat{ }2+1 |
| | Fe7[5] := x\hat{ }15+x\hat{ }13+x\hat{ }11+x\hat{ }10+x\hat{ }9+x\hat{ }5+x+1 |
| | Fe7[6] := x\hat{ }15+x\hat{ }10+x\hat{ }9+x\hat{ }8+x\hat{ }3+x\hat{ }2+x |

Fe7[7] := x\hat{ }15+x\hat{ }14+x\hat{ }13+x\hat{ }6+x\hat{ }2+1
Fe7[8] := x\hat{ }13+x\hat{ }12+x\hat{ }10+x\hat{ }9+x\hat{ }5+x\hat{ }4+x\hat{ }2+x+1

| | |
|---|---|
| > | FP17:=vector(8,[ ]): Sif:=vector(6,[ ]): |

| | |
|---|---|
| > | ts:=time( ): for jk from 1 to 1000 do |
| > | for j4 from 0 to 5 do |

| | |
|---|---|
| > | for j3 from 1 to 8 do jj:=2*j4+1: |

wr:=rem(subs(x=z\hat{ }jj,Fe7[j3]),gz7,z) mod 2: FP17[j3]:=wr: od:

| | | |
|---|---|---|
| | > | a10:=rem(FP17[1]\hat{ }2+z\hat{ }jj*FP17[2]\hat{ }2,gs7,z) mod 2: |
| | | a11:=rem(FP17[3]\hat{ }2+z\hat{ }jj*FP17[4]\hat{ }2,gz7,z) mod 2: |
| | > | aa1:=rem((a10)\hat{ }2+z\hat{ }jj*(a11)\hat{ }2,gz7,z) mod 2: |
| | > | a20:=rem(FP17[5]\hat{ }2+z\hat{ }jj*FP17[6]\hat{ }2,gz7,z) mod 2: |
| | | a21:=rem(FP17[7]\hat{ }2+z\hat{ }jj*FP17[8]\hat{ }2,gz7,z) mod 2: |
| > | | aa2:=rem(a20\hat{ }2+z\hat{ }jj*a21\hat{ }2,gz7,z) mod 2: |
| > | | Sif[j4+1]:=rem(aa1\hat{ }2+z\hat{ }jj*aa2\hat{ }2,gz7,z) mod 2: od: |
| > | | od: telap=time( )−ts; gain=evalf(228.017/(time( )−ts)); |

| | |
|---|---|
| > | #Without precoputated powers of z=alpha |

telap = 115.666
gain = 1.057077181

| | |
|---|---|
| > | #With precoputed powers |

Mbch7:=matrix(6,16,[ ]):

| | for iq from 0 to 5 do for jq from 0 to 15 do | |
|---|---|---|
| | | Mbch7[iq+1,jq+1]:=rem(z\hat{ }((2*iq+1)*jq),gz7,z) mod 2: od: od: |
| > | | FP17:=vector(8,[ ]): Sif:=vector(6,[ ]): ts:=time( ): |
| > | | for jk from 1 to 1000 do |

for j4 from 0 to 5 do

for j3 from 1 to 8 do jj:=2*j4+1:

wr:=add(Mbch7[j4+1,jo+1]*coeff(Fe7[j3],x,jo), jo=0..15) mod 2:
FP17[j3]:=wr: od:

a10:=rem(FP1711]\hat{ }2+z\hat{ }jj*FP17[2]\hat{ }2,gz7,z) mod 2:
a11::=rem(FP17[3]\hat{ }2+z\hat{ }jj*FP17[4]\hat{ }2,gz7,z) mod 2:
aa1:=rem((a10)\hat{ }2+z\hat{ }jj*(a11)\hat{ }2,gz7,z) mod 2:
a20:=rem(FP17[5]\hat{ }2+z\hat{ }jj*FP17[6]\hat{ }2,gz7,z) mod 2:
a21:=rem(FP17[7]\hat{ }2+z\hat{ }jj*FP17[8]\hat{ }2,gz7,z) mod 2:
aa2:=rem(a20\hat{ }2+z\hat{ }jj*a21\hat{ }2,gz7,z) mod 2:
Sif[j4+1]:=rem(aa\hat{ }2+z\hat{ }jj*aa2\hat{ }2,gz7,z) mod 2: od:
od:

| | |
|---|---|
| > | telap=time( )−ts; gain=evalf(228.017/(time( )−ts)); |

telap = 28.031

gain = 8.134458279

### Examples of Applications

Possible applications for the presently proposed apparatus and algorithm are the following:

### Application A: Conditional Access Structure

This scheme is used for example in PayTV access control systems. Suppose a server wants to distribute a key K to a subset of the set of all possible users, namely the subset of the people who paid for a particular content. Suppose users U₁, . . . , Uₙ are in this subset. Then the server can publish the following polynomial

$$p ( x ) = K + {\prod }_{1}^{n} ( x - h ( {x}_{i} ) )$$

where xᵢ stands for the binary string that user Uᵢ is supposed to have as a ticket and h is a hash function that the server will change each time it publishes a new polynomial.

An authorized user Uᵢ gets K by evaluating p(x) in h(xᵢ). As the polynomial can be pretty big, if the number of authorized users is big, an efficient polynomial evaluation algorithm is desirable.

So here the input is p(x), the polynomial made public by the server, and the output is p(h(xᵢ)) computed by the user Uᵢ to get K.

### Application B: Syndrome Calculation and Forney's Algorithm

These computations are key operations in the algebraic decoding of cyclic codes, like BCH and Reed-Solomon codes. Here the input is a received word r to be decoded. This is in form of a string of symbols (in the binary alphabet for example) and is transformed into a polynomial R(x) simply by considering those symbols as its coefficients.

The output we want is R(αᵢ), 1≦i≦2t, where 2t is the number of syndromes to be computed (depending on the BCH bound t, a parameter of the code in use), and α is an element of the field where the computations occur.

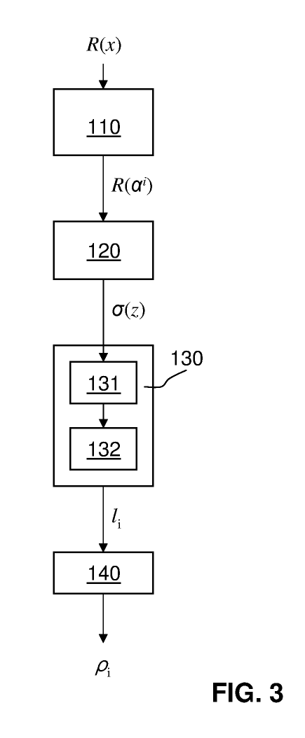

A scheme of the whole decoding procedure is illustrated in FIG. 3.

Unit 110 is a syndrome computation unit, which outputs R(αᵢ), 1≦i≦2t as said. These values are the inputs for unit 120, which produces the error locator polynomial σ(z) (usually by means of Berlekamp-Massey algorithm). Error-locating unit 130 looks for the roots of this polynomial, as they correspond to the positions lᵢ of the errors in the received word. Finally the outputs of units 120 and 130 are used in error-computing unit 140 to compute the error magnitudes ρᵢ (this step can be omitted in the binary case).

The error-locating unit 130 usually uses an algorithm known as Chien search. According to one aspect of the present invention, it is proposed instead to use the well-known Cantor-Zassenhaus algorithm (factoring module 131) first to find the roots in a representation where it is still not evident what are the corresponding error positions, then finally find the error positions by computing discrete logarithms by means of Shank's algorithm (logarithm-computing module 132). This will be explained in more detail further below.

Unit 140 applies Forney's algorithm and involves the evaluation of some polynomials built from the outputs of units 120 and 130. This step is not needed in the case of binary codes.

Application C: Secret Sharing schemes

These are (t, n)-threshold schemes based on interpolating polynomials. The secret key K is broken into pieces or shadows for n users, so that at least t users are needed to retrieve the key K, and no group of fewer than t users can do it. The sharing mechanism is the following: a server chooses a polynomial over a certain finite field, of degree t−1, with constant term K and all other coefficients randomly chosen. Then the server evaluates this polynomial in n different field elements, and the outputs are the shadows to be distributed to the users. Then any group of t can retrieve K by Lagrange interpolation.

If the number of users is large, then a fast evaluation algorithm to get the shadows to be distributed is desirable.

### Apparatus and Algorithm for Identifying Errors in a Data String: Algebraic Decoding of Cyclic Codes

In the following, application of the invention in the context of the algebraic decoding of cyclic codes [n, k, d] up to the BCH bound is illustrated. Today error correcting codes of sizes must be managed that require efficient algorithms, possibly at the limit of their theoretical minimum complexity.

For easy reference, the algebraic decoding of cyclic codes is summarized in the following: let C be an [n, k, d]cyclic code over a finite field GF(q), q=p^{s} for a prime p, with generator polynomial of minimal degree r=n−k

g(x)=x^{r}+g₁x^{r-1}+ . . . +gᵣ₋₁x+gᵣ,

g(x) dividing xⁿ−1, and let a be a primitive n-th root of unity lying in a finite field GF(p^{m}), where the extension degree is the minimum integer m such that n is a divisor of p^{m}−1

Assuming that C has BCH bound t, then g(x) has 2t roots with consecutive power exponents, so that the whole set of roots is

R={α^{l+1},α^{l+2}, . . . α^{l+2t},α^{s}^{₂ₜ₊₁}, . . . α^{s}^{ᵣ}},

where it is not restrictive to take l=0 as it is usually done.

Let R(x)=g(x)+e(x) be a received code word such that the error pattern e(x) has no more than t errors. The Gorenstein-Peterson-Zierler decoding procedure, which is a standard decoding procedure for every cyclic code up to the BCH bound, is made up of four steps:
Computation of 2t syndromes:

Sⱼ=R(α^{l+j})j=1, . . . 2t.
Computation of the error-locator polynomial

σ(z)=z^{t}+σ₁z^{t-1}+ . . . +σₜ₋₁z+σₜ
(we are assuming the worst case, that is there are exactly t errors; if there are tₑ<t errors, this step would output a polynomial of degree tₑ).
Computation of the roots of σ(z) in the form

α^{j}^{ₕ},h=1, . . . ,t,
yielding the error positions jₕ.
Computation of the error magnitudes.

Prior-art implementations of this decoding algorithm combine the computation of 2t syndromes using Horner's rule, the Berlekamp-Massey algorithm to obtain the error-locator polynomial, the Chien search to locate the errors, and the evaluation of Forney's polynomial Γ(x) to estimate the error magnitudes.

The computation of the 2t syndromes using Horner's rule requires 2tn multiplications in GF(q^{m}), which may be prohibitive when n is large. Horner's rule may be replaced by the Algorithm for evaluating polynomials according to the present invention, as discussed above. The Berlekamp-Massey algorithm has multiplicative complexity O(t²), is very efficient and will not be discussed further later on. The Chien search requires again O(tn) multiplications in GF(q^{m}). Forney's algorithm again requires O(t²). Notice that this fourth step is not required if we deal with binary codes and that both the first and the fourth steps consist primarily in polynomial evaluations, so they can benefit from any efficient polynomial evaluation algorithm, as described above.

The standard decoding procedure is satisfactory when the code length n is not too large (say <10³) and efficient implementations are set up taking advantage of the particular structure of the code. The situation changes dramatically when n is of the order of 10⁶ or larger. In this case a complexity O(tn), required by the Chien search, is not acceptable anymore. In the following, a method to make this step more efficient and practical even for large n is described.

We will follow the usual approach of focusing as above in computing the number of multiplications, as they are more expensive than sums: for example in GF(2^{m}) the cost of an addition is O(m) in space and one clock in time, while the cost of a multiplication is O(m²) in space and O(log₂ m) in time.

The syndromes are computed in the manner as described above. Once the error locator polynomial σ(z) has been computed from the syndromes using the Berlekamp-Massey algorithm, its roots represented in the form α^{l}^{ᵢ}, correspond to the error positions lᵢ, i=1, . . . , t, which are generally found by testing σ(αⁱ) for all n possible powers αᵢ with an algorithm usually referred to as the Chien search. In this approach, if σ(αᵢ)=0 an error in position i is recognized, otherwise the position is correct. However, this simple mechanism can be unacceptably slow when n is large since its complexity is O(tn). In one aspect, the present invention provides a less costly procedure.

The Cantor-Zassenhaus probabilistic factorization algorithm is very efficient in factoring a polynomial and consequently in computing the roots of a polynomial. Since σ(z) is the product of t linear factors z+ρᵢ, over GF(q^{m}), (i.e. ρᵢ is a q-ary polynomial in α of degree m-1), this factoring algorithm can be directly applied to separate these t factors. Thus, the error positions lᵢ are obtained by computing the discrete logarithm of ρᵢ=α^{l}^{ᵢ} to base α. This task can be performed by Shank's algorithm, which we revisit below. The overall expected complexity of finding the error positions with this algorithm is O(mt² log t), plus O(t\sqrt{n}), where the second addend comes from Shank's algorithm. It is evident how this complexity is better than O(n) for most cases, in particular when t is small in comparison to n.

### Cantor-Zassenhaus Algorithm

The Cantor-Zassenhaus algorithm is described here for easy reference. Only the case of characteristic 2 is treated here, which is by far the most common in practice; the general situation is described in [3, 6].

Assume that p(z) is a polynomial over GF(2^{m}) that is a product of t polynomials of degree 1 over the same field GF(2^{m}), m even (when m is odd it is enough to consider a quadratic extension and proceed as in the case of even m). Suppose that α is a known primitive element in GF(2^{m}), and set

$${l}_{m} = \frac{{2}^{m} - 1}{3} ,$$

then ρ=α^{l}^{ₘ} is a primitive cubic root in GF(2^{m}), so that ρ is a root of z²+z+1. The algorithm consists of the following steps:
1. Generate a random polynomial b(z) of degree t−1 over F₂m
2. Compute: a(z)=b(z)^{l}^{ₘ} mod p(z);
3. IF a(z)≠0, 1, ρ, ρ², THEN at least a polynomial among gcd{p(z), a(z)}, gcd{p(z), a(z)+1}, gcd{p(z), a(z)+ρ}, gcd{p(z), a(z)+ρ²}, will be a non trivial factor of p(z), ELSE repeat from point 1.
4. Iterate until all linear factors of p(z) are found.

### Remark 5.

As shown in [6], the polynomial b(z) can be chosen of the form z+β, using b(z)=z as initial choice. Let θ be a generator of the cyclic subgroup of GF*(2^{m}) of order lₘ. If

z^{lm}=ρᵢ mod σ(z),iε{1,1,2},

then each root ζₕ of σ(Z) is of the form αᵢθ^{j}. If this is the case, which does not allow us to find a factor, we repeat the test with b(z)=z+β for some β and we will succeed as soon as the elements ζₕ+β are not all of the type αⁱθ^{j} for the same iε{0, 1, 2}. This can be shown to happen probabilistically very soon, especially when the degree of σ(z) is high.

### Shank's Algorithm

Shank's algorithm can be applied to compute the discrete logarithm in a group of order n generated by the primitive root α. The exponent l in the equality

α^{l}=b₀+b₁α+ . . . +bₛ₋₁α^{s-1}

is written in the form

l=l₀+l₁┌\sqrt{n}┐

A table T is constructed with ┌\sqrt{n}┐ entries α^{l}^{₁}^{┌\sqrt{n}┐} which are sorted in some well defined order, then a cycle of length ┌\sqrt{n}┐ is started computing

Aⱼ=(b₀−b₁α+ . . . +bₛ₋₁α^{s-1})α⁻¹j=0, . . . ,┌\sqrt{2}┐−1,

and looking for Aⱼ in the Table; when a match is found with the κ-th entry, we set l₀=j and l₁=κ, and the discrete logarithm l is obtained as j+κ┌\sqrt{n}┐.

This algorithm can be performed with complexity O(\sqrt{n}) both in time and space (memory). In our scenario, since we need to compute t roots, the complexity is O(t\sqrt{n}).

### Remark 6.

We observe that the above procedure can be used to decode beyond the BCH bound, up to the minimum distance, whenever the error locator polynomial can be computed from a full set of syndromes [4, 7, 20, 23].

### Remark 7.

The Cantor-Zassenhaus algorithm finds the roots X of the error locator polynomial, then the baby-step giant-step algorithm of Shank's finds the error positions. As said in the introduction, this is the end of the decoding process for binary codes. For non-binary codes, Forney's polynomial

Γ(x)=σ(x)S(x) mod x^{2t+1},

where

S(x)=Σᵢ₌₁^{2t}Sᵢxⁱ[2],

yields the error values

$${Y}_{l} = - {X}_{l} \frac{Γ ( {X}_{l}^{- 1} )}{{σ}^{′} ( {X}_{l}^{- 1} )} .$$

Again we remark that this last step can benefit from an efficient polynomial evaluation algorithm, such as the one presented above.

### Remark 8.

Given the importance of cyclic codes over GF(2^{m}), for instance the Reed-Solomon codes that are used in any CD-ROM, or the famous Reed-Solomon code [255, 223, 33] over GF(2⁸) used by NASA ([24]), an efficient evaluation of polynomials over GF(2^{m}) in points of the same field is of the greatest interest. In the previous remarks we have shown that efficient methods do exist, even more, in particular scenarios additional gains can be obtained by a clever choice of the parameters, for example choosing L as a factor of m that is close to the optimum given above, together with some arrangements as explained below.

The idea will be illustrated considering the decoding of the above mentioned Reed-Solomon code, namely we show how to obtain the 32 syndromes.

Let

r(x)=Σᵢ₌₀²⁵⁴rᵢxⁱ,rᵢεF₂_{⁸},

be a received code word of a Reed Solomon code [255, 223, 33] generated by the polynomial

g(x)=┌ⁱ⁼¹³²(x−αⁱ),

with α a primitive element of GF(2⁸), i.e. a root of x⁸+x⁵+x³+x+1. Our aim is to evaluate the syndromes

Sⱼ=r(α^{j}),j=1, . . . ,32.

We can argue in the following way. The power β=α¹⁷ is a primitive element of the subfield GF(2⁴), it is a root of the polynomial x⁴+x³+1, and has trace 1 in GF(2⁴). Therefore, a root δ of z²+z+β is not in GF(2⁴), but it is an element of GF(2⁸), and every element of GF(2⁸) can be written as a+bδ with a,bεGF(2⁴). Consequently, we can write r(x)=r₁(x)+δr₂(x) as a sum of two polynomials over GF(2⁴), evaluate each rᵢ(x) in the roots α^{j} of g(x), and obtain each syndrome

Sⱼ=r(α^{j})=r₁(α^{j})+δr₂(α^{j})

with one multiplication and one sum.

Now, following our proposed scheme, if p(x) is either r₁(x) or r₂(x), in order to evaluate p(α^{j}) we consider the decomposition

p(x)=(p₀+p₂x+ . . . +p₂₅₄x¹²⁷)²+x(p₁+p₃x+ . . . +p₂₅₃x¹²⁶)²,

where we have not changed the coefficients computing σ⁻¹ for each of them, as a convenient Frobenius automorphism will come into play later. Now, each of the two parts can be decomposed again into the sum of two polynomials of degree at most 63, for instance

p₀+p₂x+ . . . +p₂₅₄x¹²⁷=(p₀+p₄x+ . . . +p₂₅₂x⁶³)²+x(p₂+p₆x+ . . . +p₂₅₄x⁶³)²

and at this stage we have four polynomials to be evaluated. The next two steps double the number of polynomials and halve their degree; we write just one polynomial per each stage

p₀+p₄x+ . . . +p₂₅₂x⁶³=(p₀+p₈x+ . . . +p₂₄₈x³¹)²+x(p₄+p₁₂x+ . . . +p₂₅₂x³¹)²

p₀+p₈x+ . . . +p₂₄₈x³¹=(p₀+p₁₆x+ . . . +p₂₄₀x¹⁵)²+x(p₈+p₂₄x+ . . . +p₂₄₈x¹⁵)²

Since we choose to stop the decomposition at this stage, we have to evaluate 16 polynomials of degree at most 15 with coefficients in GF(2⁴), but before doing this computation we should perform the inverse Frobenius automorphism σ⁻⁴ on the coefficients, however σ⁻⁴(pᵢ)=pᵢ because the coefficients are in GF(2⁴) and any element β in this field satisfies the condition

β²^{⁴}=β.

Now, let K be the number of code words to be decoded. It is convenient to compute only once the following field elements:

αⁱ,i=2, . . . ,254.

(this requires 253 multiplications); and

αⁱ·β^{j} for i=0, . . . ,254 and j=1, . . . ,14,

which requires 255×14=3570 multiplications.

Then only sums (that can be performed in parallel) are required to evaluate 16 polynomials of degree 15 for each α^{j}, j=1, . . . ,32. Once we have the values of these polynomials, in order to reconstruct each of r₁(α^{j}) or r₂(α^{j}), we need
16+8+4+2 squares
8+4+2+1 multiplications (and the same number of sums).

Summing up, every r(α^{j})=r₁(α^{j})+δr₂(α^{j}) is obtained with 2×45+1=91 multiplications. Then the total cost of the computation of 32 syndromes drops down from 31+32×254=8159 with Horner's rule to 32×91+3570+253=6735. Since we have K code words the total cost drops from 31+8128 K to 3823+2912 K, with two further advantages:
many operations can be parallelized, so that the speed is further increased;
the multiplications can be performed in GF(2⁴) instead of GF(2⁸), if we write α^{j}=αⱼ+δβⱼ; the number of multiplications could increase but their execution would be much faster.

Clearly, these decoding schemes can be generalized for cyclic codes over any GF(p^{m}) with m not prime.

### Numerical Example

In the previous sections we presented methods to compute syndromes and error locations in the GPZ decoding scheme of cyclic codes up to their BCH bound, which are asymptotically better than the classical algorithms. The following example illustrates the complete new procedure.

Consider a binary BCH code [63; 45; 7] with generator polynomial

g(x)=x¹⁸+x¹⁷+x¹⁴+x¹³+x⁹+x⁷+x⁵+x³+1

whose roots are
α, α², α⁴, α⁸, α¹⁶, α³², α³, α⁶, α¹², α²⁴, α⁴⁸, α³³, α⁵, α¹⁰, α²⁰, α⁴⁰, α¹⁷, α³⁴,
   thus the BCH bound is 3.

Let c(x)=g(x)I(x) be a transmitted code word, and the received word be

r(x)=x⁵⁷+x⁵⁶+x⁵³+x⁵²+x⁵⁰+x⁴⁸+x⁴⁶+x⁴⁴+x⁴²+x³⁹+x³¹+x¹⁸+x¹⁷+x¹⁴+x¹³+x⁷+x⁵+x³+1

where three errors occurred. The 6 syndromes are

$$\{ \begin{matrix}{S}_{1} = {α}^{5} + {α}^{2} + α \\ {S}_{2} = {S}_{1}^{2} \\ {S}_{3} = {α}^{5} + {α}^{4} + {α}^{3} + {α}^{2} + α \\ {S}_{4} = {S}_{1}^{4} \\ {S}_{5} = {α}^{5} + {α}^{2} + 1 \\ {S}_{6} = {S}_{3}^{2} .\end{matrix}$$

For example, S₁ has been computed considering r(x) as a sum of the polynomials

$$\{ \begin{matrix}{r}_{e 1} = {x}^{56} + {x}^{52} + {x}^{50} + {x}^{48} + {x}^{46} + {x}^{44} + {x}^{42} + {x}^{18} + {x}^{14} + 1 \\ {r}_{o 1} = x ( {x}^{56} + {x}^{52} + {x}^{38} + {x}^{30} + {x}^{16} + {x}^{12} + {x}^{6} + {x}^{4} + {x}^{2} ) .\end{matrix}$$

Each square polynomial splits into two polynomials

$$\{ \begin{matrix}{r}_{ee 1} = {x}^{28} + {x}^{26} + {x}^{24} + {x}^{22} + 1 \\ {r}_{oe 1} = x ( {x}^{24} + {x}^{22} + {x}^{20} + {x}^{8} + {x}^{6} ) \\ {r}_{eo 1} = {x}^{28} + {x}^{26} + {x}^{8} + {x}^{6} + {x}^{2} \\ {r}_{oo 1} = x ( {x}^{18} + {x}^{14} + {x}^{2} + 1 ) .\end{matrix}$$

Again each square polynomial splits into two polynomials

$$\{ \begin{matrix}{r}_{eee 1} = {x}^{14} + {x}^{12} + 1 \\ {r}_{oee 1} = x ( {x}^{12} + {x}^{10} ) \\ {r}_{eoe 1} = {x}^{12} + {x}^{10} + {x}^{4} \\ {r}_{ooe 1} = x ( {x}^{10} + {x}^{2} ) \\ {r}_{eeo 1} = {x}^{14} + {x}^{4} \\ {r}_{oeo 1} = x ( {x}^{12} + {x}^{2} + 1 ) \\ {r}_{eoo 1} = 1 \\ {r}_{ooo 1} = x ( {x}^{8} + {x}^{3} + 1 ) .\end{matrix}$$

Therefore we need the following powers
α⁷, α⁶, α⁵, α⁴, α³, α²
   in order to evaluate the 8 polynomials, this requires 6 multiplications, and going back we need successively 4 products and 8 squares, 2 products and 4 squares, 1 product and 2 squares, in conclusion we need 6+12+6+3=27 products to evaluate S₁. If a normal basis is used, the proposed method requires 6+4+2+1=13 products and 8+4+2=14 squares whose cost in complexity is in this case negligible with respect to the product [5, 12]. The coefficients of the error locator polynomial turn out to be

$$\{ \begin{matrix}{σ}_{1} = {α}^{5} + {α}^{2} + α \\ {σ}_{2} = {α}^{3} + {α}^{4} + α \\ {σ}_{3} = {α}^{4} + {α}^{5} + {α}^{2} .\end{matrix}$$

The roots of σ(z) are computed as follows using the Cantor-Zassenhaus algorithm. Let ρ=α²¹ be a cube root of the unity, consider a random polynomial, for instance Z+ρ, of degree less than 3 and compute

a(z)=(z+ρ)²¹ modulo σ(z)

(the exponent of z+ρ is (2^{m}−1)/3=21):

(α⁵+α⁴+α²+α+1)z²+(α³+α+1)z+α⁵+α⁴+x³+1.

In this case a(z) has no root in common with σ(z), while

gcd(a(z)+1,σ(z))=z+(α⁴+α³+1)(l−31),

gcd(a(z)+ρ,σ(z))=z+(α⁵+α⁴+α²+1)(l−9),

gcd(a(z)+ρ²,σ(z))=z+(α³+α)(l−50),

The error positions have been obtained using Shank's algorithm with a table of 8 entries, and a loop of length 8 for each root, for a total of 24 searches versus 63 searches of Chien's search.

### REFERENCES

[1]E. Berlekamp, Algebraic Coding Theory, McGraw-Hill, New York, 1968.
[2]R. E. Blahut, Algebraic Codes for Data Transmission, Cambridge University Press, Cambridge, 2003.
[3]D. G. Cantor, H. Zassenhaus, A new Algorithm for Factoring Polynomials over Finite Fields, Math. of Computation, Vol. 36, N. 154, April 1981, pp. 587-592.
[4]M. Elia, Algebraic Decoding of the (23; 12; 7) Golay Code, IEEE Trans. on Information Theory, vol. IT-33, No. 1, January 1981, p. 150-151.
[5]M. Elia, M. Leone, On the Inherent Space Complexity of Fast Parallel Multipliers for GF(2^{m}), IEEE Trans. on Computer, vol. 51, N. 3, March 2002, p. 346-351.
[6]M. Elia, D. Schipani, Improvements on Cantor-Zassenhaus Factorization Algorithm, www.arxiv.org, 2010.
[7]G.-L. Feng, K. K. Tzeng, Decoding cyclic and BCH codes up to actual minimum distance using nonrecurrent syndrome dependence relations, IEEE Trans. on Inform. Th., IT-37, No. 6, 1991, pp. 1716-1723.
[8]J. von zur Gathen, J. Gerhard, Modern Computer Algebra, Cambridge Univ. Press, 1999.
[9]S. W. Golomb, Shift Register Sequences, Aegean Park Press, Laguna Hills, 1982.
[10]J. Hong, M. Vetterli, Simple Algorithms for BCH Decoding, IEEE Trans. on Communications, Vol. 43, No. 8, August 1995, pp. 2324-2333.
[11]J. C. Interlando, E. Byrne, J. Rosenthal, The Gate Complexity of Syndrome Decoding of Hamming Codes, ACA, 2004.
[12]D. Jungnickel, Finite Fields, Structure and Arithmetics, Wissenschaftsverlag, Mannheim, 1993.
[13]D. E. Knuth, The Art of Computer Programming, Seminumerical algorithms, vol. II, Addison-Wesley, Reading Massachussetts, 1981.
[14]R. Lidl, H. Niederreiter, Finite Fields, Addison-Wesley, Reading, Mass., 1986.
[15]F. J. MacWilliams, N. J. A. Sloane, The Theory of Error-Correcting Codes, North Holland, N.Y., 1977.
[16]J. L. Massey, Shift-Register Synthesis and BCH decoding, IEEE Trans. on Inform. Th., IT-15, 1969, pp. 122-127.
[17]R. J. McEliece, Finite Fields for Computer Scientists and Engineers, Kluwer Academic Press, Boston, 1987.
[18]W. W. Peterson, E. J. Weldon, Error-Correcting Codes, MIT, New York, 1981.
[19]V. S. Pless, W. C. Huffman, Handbook of Coding Theory, vol. I and II, Noth-Holland, Amsterdam, 1998.
[20] Reed, I. S., Truong, T. K., Chen, X., Yin, The algebraic decoding of the (41; 21; 9) quadratic residue code IEEE Trans. on Inform. Th., IT-38, No. 3, 1992, pp. 974-986.
[21]S. B. Wicker, Error control systems for Digital Communication and Storage, Prentice-Hall, Englewood Cliffs, N.J., 1995.
[22]S. B. Wicker, V. K. Bhargava, eds. Reed-Solomon codes and their applications, IEEE Press, Piscataway, N.J., 1994.

1. An apparatus for evaluating an input polynomial of degree n over a finite field of order p^{r}, in an element γ of a finite field of order p^{m}, where p denotes a prime number, m denotes a positive integer, and r is a divisor of m, the apparatus comprising:
a coefficient receiving module for receiving the n+1 coefficients of the input polynomial;
a decomposition/evaluation module configured to iteratively decompose the input polynomial in a number of L iterations, wherein L is a positive integer, wherein in each iteration the input polynomial or a set of polynomials resulting from the previous iteration are decomposed into sums of i-th powers of x with i=0, . . . , p−1, multiplied by p-th powers of transformed polynomials, and wherein each transformed polynomial has a degree that is smaller by a factor of at least p as compared to the polynomial to which the iteration is applied, and to evaluate the decomposed input polynomial in an element γ, and
an output module for outputting the value of the decomposed input polynomial in the element γ.

2. The apparatus of claim 1, wherein the decomposition/evaluation module is configured to carry out:
reordering each polynomial P(x) to which the iteration is applied as a sum
P₀(x^{p})+xP₁(x^{p}) . . . +x^{p-1}Pₚ₋₁(x^{p})
of p terms of form xⁱPᵢ(x^{p}), wherein each polynomial Pᵢ(x^{p}) collects powers of x of the form x^{ap+i}, where a is a positive integer and i=0, . . . , p−1;
transforming the coefficients of the polynomials Pᵢ(x) by application of the inverse Frobenius automorphism to obtain a transformed polynomial Pᵢ⁻¹(x); and
reordering the polynomial to which the iteration is applied as a sum of i-th powers of x with i=0, . . . , p−1, multiplied by p-th powers of the transformed polynomials:
P₀⁻¹(x)^{p}+xP₁⁻¹(x)^{p} . . . +x^{p-1}Pₚ₋₁⁻¹(x)^{p},
wherein each transformed polynomial Pᵢ⁻¹(x) has a degree that is smaller by at least a factor of p as compared to the polynomial to which the iteration is applied.

3. The apparatus of claim 1, further comprising an optimization module for determining a preferred number L of iterations, the optimization module being configured to compute a number L that is expected to minimize a cost function substantially representing the total computational cost for decomposing the input polynomial and evaluating the decomposed input polynomial.

4. The apparatus of claim 1, wherein the decomposition/evaluation module comprises a memory module for storing a coefficient matrix (M) of size p^{L}×┌n/p^{L}┐, the decomposition/evaluation module being configured to store the at most ┌n/p^{L}┐ coefficients of each of the p^{L} transformed polynomials in said coefficient matrix.

5. The apparatus of claim 1, wherein the decomposition/evaluation module comprises a memory structure for storing a vector (A) of powers of the element γ with exponents from 1 to ┌n/p^{L}┐, wherein the decomposition/evaluation module is configured to pre-compute said vector, and to write said vector to the memory structure.

6. The apparatus of claim 5, wherein the decomposition/evaluation module comprises a memory module for storing a coefficient matrix (M) of size p^{L}=┌n/p^{L}┐, wherein the decomposition/evaluation module is configured to fill said coefficient matrix (M) with coefficients representing the input polynomial, to multiply said coefficient matrix with said vector (A) of powers to obtain a result vector (Out) of size p^{L}, and to compute the value of the input polynomial in element γ by recursively carrying out operations on said result vector (Out).

7. The apparatus of claim 1,
further comprising an initialization submodule which is configured to initially decompose the input polynomial into a sum of polynomials over a finite field of order p, multiplied by i-th powers of a root of an irreducible polynomial of degree r, and
wherein the decomposition/evaluation module is configured to further iteratively decompose said polynomials over said finite field of order p.

8. An error identification apparatus for identifying errors in a data string based on a cyclic code, the error identification apparatus comprising a syndrome evaluation device for evaluating a set of syndromes for said data string, characterized in that the syndrome evaluation device comprises an apparatus of claim 1, configured to evaluate said syndromes as input polynomials.

9. An error identification apparatus for identifying errors in a data string based on a cyclic code, in particular, an error correcting apparatus according to claim 8, comprising:
a syndrome evaluation device for evaluating a set of syndromes from said data string; and
an error locator device for computing an error locator polynomial based on the syndromes and for computing the error positions based on the error locator polynomial,
characterized in that the error locator device comprises:
a factoring module for finding the roots of the error-locator polynomial, the factoring module being configured to factor the error-locator polynomial by application of the Cantor-Zassenhaus algorithm and to output the resulting roots of the error-locator polynomial, and
a logarithm-computing module for computing a discrete logarithm of the roots, to obtain the error positions.

10. The error correcting apparatus of claim 9, wherein the logarithm-computing module is configured to apply Shank's algorithm to the roots of the error-locator polynomial obtained by the factoring module.

11. A computer-implemented method of evaluating an input polynomial of degree n over a finite field of order p^{r}, in an element γ of a finite field of order p^{m}, where p denotes a prime number, m denotes a positive integer, and r is a divisor of m, the method using a computer and comprising:
loading the n coefficients of the input polynomial into a memory of said computer;
iteratively decomposing the input polynomial in a number of L iterations, wherein L is a positive integer, wherein in each iteration the input polynomial or a set of transformed polynomials resulting from the previous iteration are decomposed into sums of i-th powers of x with i=0, . . . , p−1, multiplied by p-th powers of transformed polynomials, and wherein each transformed polynomial has a degree that is smaller by a factor of at least p as compared to the polynomial to which the iteration is applied, and the decomposed input polynomial being evaluated in the element γ, and
outputting the value of the decomposed input polynomial in the element γ.

12. The method of claim 11, wherein iteratively decomposing the input polynomial comprises:
reordering each polynomial P(x) to which the iteration is applied as a sum
P₀(x^{p})+xP₁(x^{p}) . . . +x^{p-1}Pₚ₋₁(x^{p}),
of p terms of form xⁱPᵢ(x^{p}), wherein each polynomial Pᵢ(x) collects powers of x of the form x^{ap+i}, where a is a positive integer and i=0, . . . , p−1;
transforming the coefficients of each of the polynomials Pᵢ(x) by application of the inverse Frobenius automorphism to obtain a transformed polynomial Pᵢ⁻¹(x); and
reordering the polynomial to which the iteration is applied as a sum of i-th powers of x with i=0, . . . , p−1, multiplied by p-th powers of the transformed polynomials:
P₀⁻¹(x)^{p}+xP₁⁻¹(x)^{p} . . . +x^{p-1}Pₚ₋₁⁻¹(x)^{p},
wherein each transformed polynomial Pᵢ⁻¹(x) has a degree that is smaller by at least a factor of p as compared to the polynomial to which the iteration is applied.

13. The method of claim 11, further comprising the step of determining a preferred number L of iterations by minimizing a cost function for decomposing the input polynomial and evaluating the decomposed input polynomial, wherein the step of iteratively decomposing the input polynomial is subsequently carried out with the preferred number of L iterations.

14. The method of any claim 11, wherein the coefficients of the input polynomial and/or of the transformed polynomials are stored in a coefficient matrix of size P^{L}×┌n/p^{L}┐.

15. The method of claim 11,
wherein the input polynomial is initially decomposed into a sum of polynomials over a finite field of order p, multiplied by i-th powers of a root of an irreducible polynomial of degree r, and
wherein said polynomials over said finite field of order p are iteratively further decomposed.

16. The method of claim 11, wherein the input polynomial is evaluated to compute syndromes in an error correcting algorithm for correcting an error in a data string based on a cyclic code.

17. A computer-implemented method of identifying errors in a data string based on a cyclic code, the method using a computer and comprising:
receiving said data string in the computer,
evaluating a set of syndromes for said data string;
computing an error-locator polynomial based on the syndromes; and
computing the error positions based on the error-locator polynomial, characterized in that the step of computing the error positions comprises:
finding the roots of the error-locator polynomial by factoring the error-locator polynomial by application of the Cantor-Zassenhaus algorithm,
computing a discrete logarithm of the roots, to obtain the error positions.

18. The method of claim 17, wherein the logarithm is computed by applying Shank's algorithm.
